(19) United States
(12) Patent Application Publication
(10) Pub. No.: US 2018/0312997 A1
(43) Pub. Date: Nov. 1, 2018

(54) CRUCIBLE STRUCTURE AND MANUFACTURING METHOD THEREOF AND SILICON CRYSTAL STRUCTURE AND MANUFACTURING METHOD THEREOF

(71) Applicant: AUO Crystal Corporation, Taichung City (TW)

(72) Inventors: Tse-Meng Yeh, New Taipei City (TW); Ya-Lu Tsai, Taichung City (TW)

(73) Assignee: AUO Crystal Corporation, Taichung City (TW)

(21) Appl. No.: 15/960,517

(22) Filed: Apr. 23, 2018

(30) Foreign Application Priority Data
Apr. 28, 2017 (TW) 106114197

(51) Int. Cl. C30B 35/00; C30B 29/06; C30B 15/10; C03B 19/06; C03C 17/10; C03C 17/22; C03C 17/25

(52) U.S. Cl. CPC C30B 35/002; C30B 29/06; C30B 15/10; C03B 19/063; C03C 2218/112; C03C 17/225; C03C 17/25; C03B 2201/02; C03C 17/10

(57) ABSTRACT

A crucible structure is adapted for manufacturing a silicon crystal structure. The crucible structure includes a crucible body and a release coating layer. A material of the crucible body includes silicon dioxide. The release coating layer directly covers the crucible body, and a material of the release coating layer includes barium silicate. The barium silicate is a continuous film to contact the silicon crystal structure, and a thickness of the release coating layer is between 35 μm and 350 μm.

### CROSS-REFERENCE TO RELATED APPLICATION

This application claims the priority benefit of Taiwan application serial no. 106114197, filed on Apr. 28, 2017. The entirety of the above-mentioned patent application is hereby incorporated by reference herein and made a part of this specification.

### BACKGROUND OF THE INVENTION

### Field of the Invention

The invention is related to a crucible structure and a manufacturing method thereof as well as a silicon crystal structure and a manufacturing method thereof, and particularly to a crucible structure for manufacturing a silicon crystal structure and a manufacturing method thereof as well as a silicon crystal structure using the crucible structure and a manufacturing method thereof.

### Description of Related Art

Currently the manufacturing method of multi-ingot is carried in the following sequence: filling a quartz crucible with a silicon material; subsequently, the silicon material is heated to be melted into a molten silicon material; afterwards, the molten silicon material is cooled and solidified to form multi-ingot; finally, the quartz crucible is removed. In order to separate the multi-ingot from the quartz crucible, typically a layer of silicon nitride is sprayed on the surface of quartz crucible as a releasing agent to avoid that the silicon material is adhered to the quartz crucible after reaction. In the cooling process, since the ratio of cooling and contraction for silicon ingot is different from that of the quartz crucible, pulling is occurred and crystal ingot is subsequently cracked. However, the adhesion between the silicon nitride powder is not strong, in the crystal-growing process, there is a high chance that a part of the silicon nitride powder falls into the crystal ingot and forms defect derived from impurities. In addition, since the silicon nitride is expensive, the high cost causes problems if silicon nitride is used as the coating layer for quartz crucible.

Moreover, in the current manufacturing method of single ingot, when the quartz crucible and silicon material are heated, the crucible gradually generates cristobalite having a loose structure. In order to generate cristobalite with higher density, a little amount of barium compound (e.g., between 0.6×10⁻⁴ g/cm² and 0.9×10⁻⁴ g/cm²) is coated on the surface of inner wall of the crucible, thereby forming a little amount of barium silicate to facilitate formation of a cristobalite discontinuous film having a thickness of not greater than 30 μm so as to prevent reaction between the silicon material and crucible, instead of being used as a releasing agent. Furthermore, in the process of forming single crystal, since a pulling method is used, the single crystal structure is not in direct contact with the quartz crucible.

### SUMMARY OF THE INVENTION

The invention provides a crucible structure which may reduce the manufacturing cost.

The invention further provides a manufacturing method of a crucible structure for manufacturing the crucible structure.

The invention further provides a manufacturing method of a silicon crystal structure via the crucible structure, which may lower the manufacturing cost and effectively reduce or avoid the probability that the impurity falls into the silicon crystal structure.

The invention further provides a silicon crystal structure which is grown via the crucible structure.

The crucible structure of the invention is adaptable for manufacturing a silicon crystal structure. The crucible structure comprises a crucible body and a release coating layer. The material of the crucible body comprises silicon dioxide. The release coating layer directly covers the crucible body, and the material of the release coating layer comprises barium silicate. The barium silicate is a continuous film for contacting the silicon crystal structure, and the thickness of the release coating layer is between 35 μm and 350 μm.

In the manufacturing method of crucible structure of the invention, the crucible structure is adaptable for manufacturing a silicon crystal structure. The manufacturing method of the crucible structure comprises the following steps: providing a crucible body, wherein the material of the crucible body comprises silicon dioxide; coating a raw material of release coating layer containing a barium compound material on the crucible body; heating the crucible body and the raw material of release coating layer to form a release coating layer that directly covers the crucible body; the material of the release coating layer comprises barium silicate, and the barium silicate is a continuous film for contacting the silicon crystal structure, wherein the thickness of the release coating layer is between 35 μm and 350 μm.

In the invention, the manufacturing method of a silicon crystal structure comprises the following steps: providing a crucible body, wherein the material of the crucible body comprises silicon dioxide; coating a raw material of release coating layer containing a barium compound material on the crucible body; filling the crucible body with a silicon material, wherein the raw material of release coating layer is disposed between the crucible body and the silicon material; heating the crucible body, the raw material of release coating layer and the silicon material to a first temperature to form a release coating layer that directly covers the crucible body; the material of the release coating layer comprises barium silicate, and the barium silicate is a continuous film for contacting the silicon crystal structure, wherein the thickness of the release coating layer is between 35 μm and 350 μm; heating the crucible body, the release coating layer and the silicon material from a first temperature to a second temperature so that the silicon material is formed into a molten silicon material; cooling the crucible body so that the molten silicon material is formed into a silicon crystal structure that is directly in contact with the crucible body.

In the invention, the silicon crystal structure is grown via the crucible structure.

Based on the above, the crucible structure of the invention uses the release coating layer that contains barium silicate as the material to replace conventional purity silicon nitride layer, wherein the barium silicate is a continuous film for contacting the silicon crystal structure, and the thickness of the release coating layer is between 35 μm and 350 μm. As compared with the spraying cost of conventional crucible, the release coating layer used for the crucible structure of the invention not only can effectively lower the manufacturing cost, but also can effectively reduce or avoid the probability that impurity falls into the silicon crystal structure formed in the subsequent process.

In addition, in the manufacturing method of the silicon crystal structure of the invention, the formation of the release coating layer and silicon crystal structure are combined as a single batch reaction. That is, the raw material of release coating layer is reacted with the crucible body first to form the release coating layer (which comprises barium silicate as the material) that directly covers the crucible body, and the silicon crystal structure is formed afterwards. The above method can avoid the problem that high temperature causes the crucible body to be softened while ensuring completeness of reaction of the release coating layer. Accordingly, the cost required for performing spraying on the crucible body can be decreased, and the probability that impurity falls into the silicon crystal structure can be effectively reduced or avoided.

In order to make the aforementioned features and advantages of the invention more comprehensible, embodiments accompanying figures are described in detail below.

### BRIEF DESCRIPTION OF THE DRAWINGS

FIG. 1A is a schematic view illustrating a crucible structure according to an embodiment of the invention.

FIG. 1B is a schematic view illustrating a crucible structure according to another embodiment of the invention.

FIGS. 2A to 2C are schematic views illustrating a manufacturing method of a crucible structure according to an embodiment of the invention.

FIGS. 3A to 3D are schematic views illustrating a manufacturing method of a silicon crystal structure according to an embodiment of the invention.

FIGS. 4A to 4I are structural views of a release coating layer of the invention in various forms observed by an electron microscope.

FIG. 5 shows the actual silicon crystal structure of the invention.

### DESCRIPTION OF EMBODIMENTS

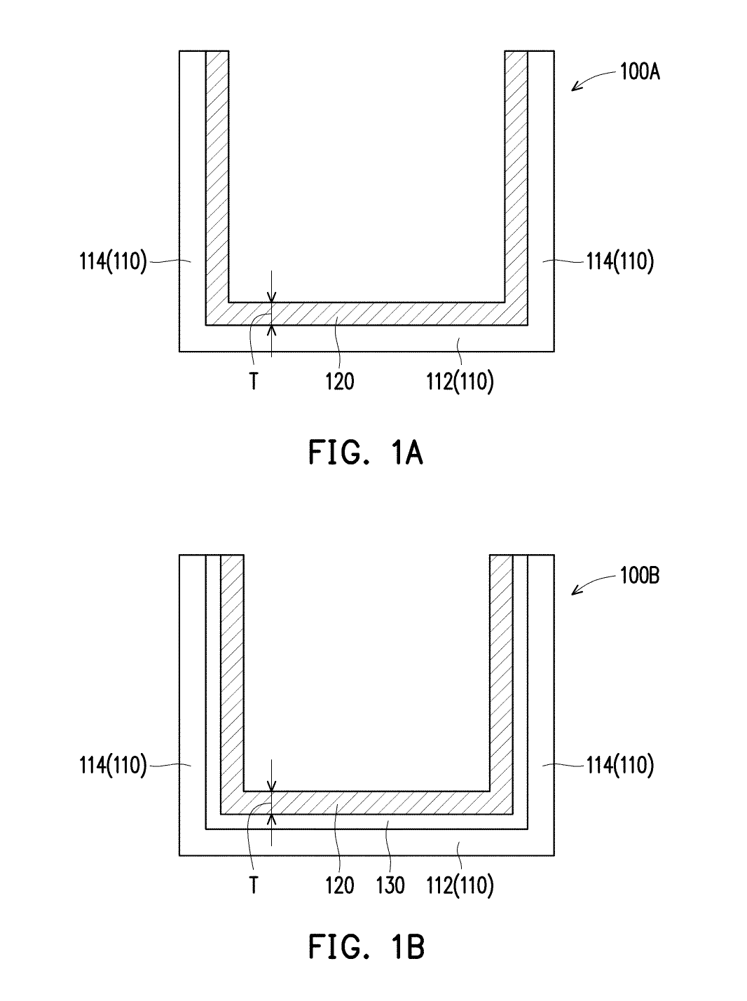

FIG. 1A is a schematic view illustrating a crucible structure according to an embodiment of the invention. Referring to FIG. 1A, in the embodiment, a crucible structure 100A includes a crucible body 110 and a release coating layer 120. The material of the crucible body 100 includes silicon dioxide. The release coating layer 120 directly covers the crucible body 110, and the material of the release coating layer 120 includes barium silicate. The barium silicate is a continuous film for directly contacting the silicon crystal structure (now shown), and a thickness T of the release coating layer 120 is between 35 μm and 350 μm.

Specifically, the crucible structure 100 in the embodiment is adapted for manufacturing a silicon crystal structure (not shown) such as multi-ingot, quasi-single crystal ingot or casted single ingot. The material of the crucible body 110 includes silicon dioxide. In other words, the crucible body 110 may be pure silicon dioxide crucible, also known as quartz crucible. Alternatively, the inner layer of the crucible body 110 is silicon dioxide, and the outer layer of the crucible body 110 is graphite, silicon carbide or other materials. The crucible body 110 has a bottom surface 112 and a plurality of side surfaces 114 which are connected to the bottom surface 112. Herein, the crucible body 110 is formed by hot-pressing quartz sand. As compared with silicon dioxide crucible that is formed by casting dissolved quartz sand for pulling the single crystal structure, the above crucible body has a relatively loose structure (or porosity is relatively high), and the surface thereof is rougher. Alternatively, the inner wall of the crucible body 110 has a center-line average roughness value (Ra) between 5 μm and 35 μm. In this manner, the material of the release coating layer 120 has a better adhesion to the surface of the crucible body 110 with more amount and lower cost.

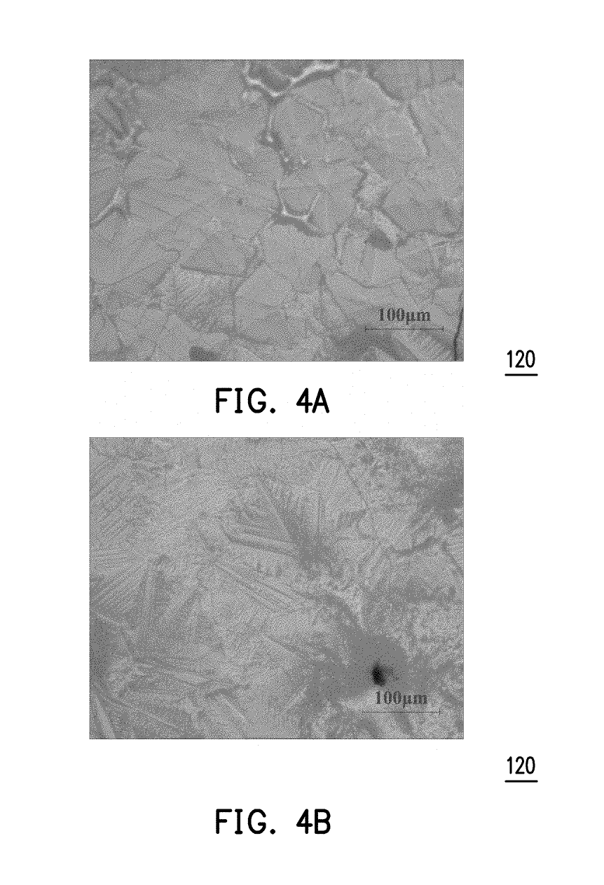

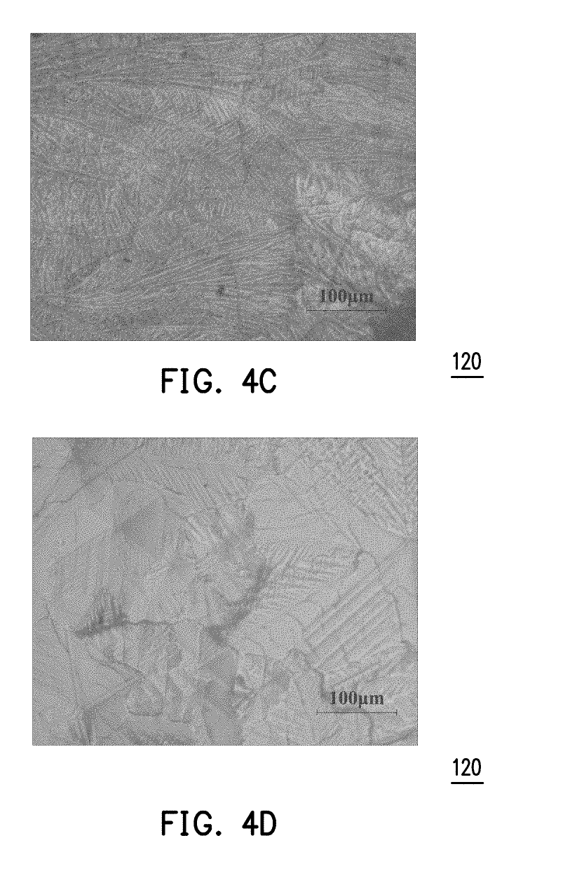

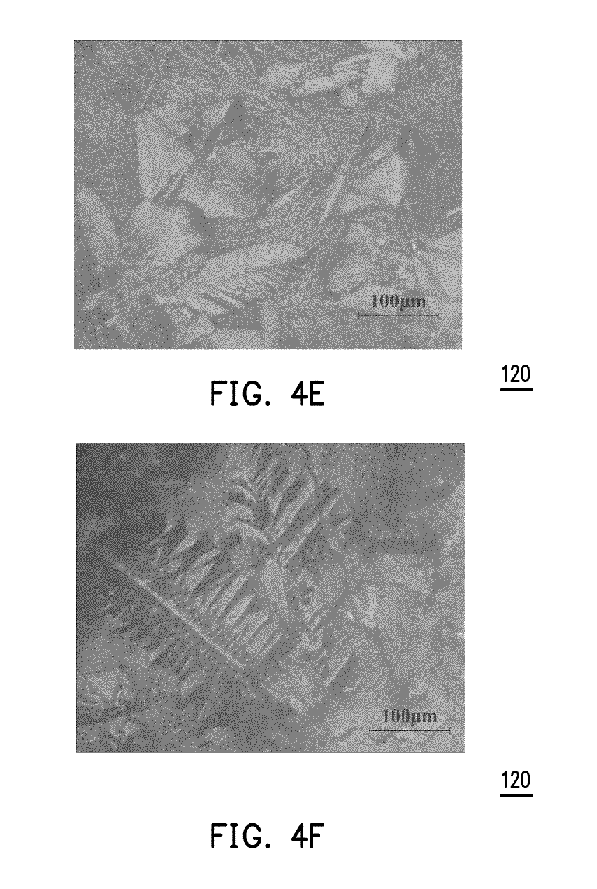

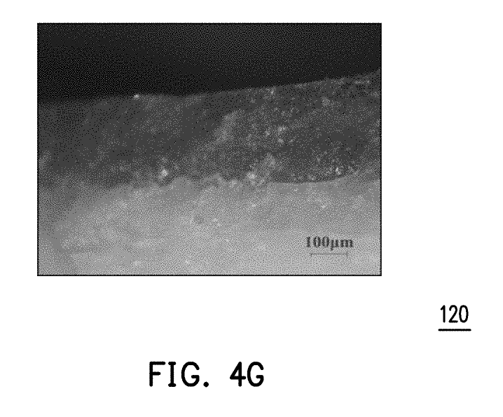

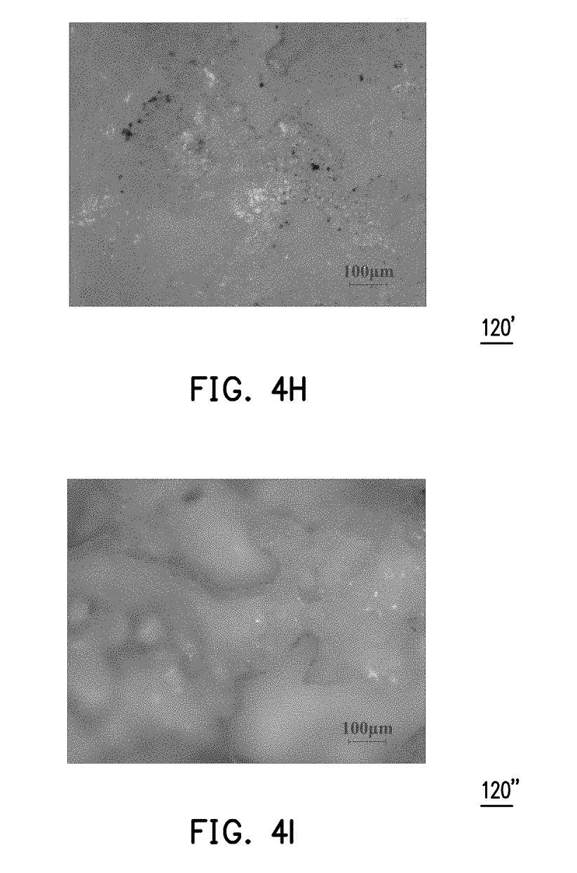

Further referring to FIG. 1A, the release coating layer 120 in the embodiment directly covers the bottom surface 112 and the side surface 114 of the crucible body 110. Herein, the release coating layer 120 may be a barium silicate coating layer. In the embodiment, the release coating layer 120 may be formed by directly using barium carbonate as a reactant to be directly reacted with silicon dioxide (i.e. the material of crucible body 110), wherein the barium carbonate may be directly derived. Alternatively, in other embodiment, the barium silicate may be obtained by reacting barium hydroxide with carbon dioxide in the air; the invention provides no limitation thereto. In particular, the barium silicate in the embodiment is realized as a continuous film, wherein the release coating layer 120 has a lattice pattern. Referring to FIGS. 4A to 4F, a thickness T of the release coating layer 120 is between 35 μm and 350 μm. Referring to FIG. 4G, the thickness T of the release coating layer 120 within the range can effectively stop the silicon material (not shown) from attacking the crucible body 110 in the subsequent crystal-growing process, and effectively protect the crucible body 110. If the thickness T of the release coating layer 120 is too thin, the release coating layer 120 may be stuck to the crucible body and cannot be easily released. On the other hand, if the thickness T of the release coating layer 120 is too thick, powder is likely to peel off the release coating layer or the release coating layer might peel off. In addition, continuous barium silicate (i.e. release coating layer 120) has excellent adhesion to the crucible body 110. The photo in FIG. 4G shows that the release coating layer 120 and the crucible body 110 are fully and tightly adhered together so that contamination of impurity can be effectively reduced. Moreover, the lifespan of carrier of the silicon crystal structure on the bottom surface 112 and side surface 114 adjacent to the crucible body 110 in the subsequent process can be improved as well.

It should be pointed out that, in the embodiment, if the release coating layer 120 is formed by directly reacting the barium carbonate as the reactant with silicon dioxide (i.e. the material of crucible body 110), then the amount of barium carbonate to be coated is, for example, 1.35×10^{-4 g}/mm². In other embodiments, the amount of barium compound material may be between 0.3×10^{-2 g}/cm² and 5×10^{-2 g}/cm², thereby directly forming the continuous barium silicate film instead of a continuous cristobalite film. In addition, since the crucible structure 100A is relatively loose, it is relatively difficult for the cristobalite to be generated. Even if a little amount of cristobalite is generated, a continuous cristobalite film is unlikely to be formed.

It should be indicated that the following embodiments use the reference numerals and a part of the descriptions mentioned in the previous embodiments, wherein the same reference numbers are used to denote identical or similar elements. Meanwhile, the same technical content is omitted. Please refer to the previous embodiments for the omitted descriptions; no repetitions are incorporated into the following embodiments.

FIG. 1B is a schematic view illustrating a crucible structure according to another embodiment of the invention. Referring to FIGS. 1A and 1B, a crucible structure 100B in the embodiment is similar to the crucible structure 100A in FIG. 1A; the difference between them is that the crucible structure 100B in the embodiment further includes a middle layer 130 disposed between the crucible body 110 and the release coating layer 120. The middle layer 130 includes silica having a weight percentage between 80% and 100%. With the high purity silica as a middle layer, it is possible to avoid permeation of impurities. Herein, the release coating layer 120 is formed by using barium carbonate as a reactant to be directly reacted with the silica in the middle layer 130.

It should be mentioned that, in other embodiments, the release coating layer 120 may further contain silicon nitride, wherein the ratio of the barium silicate to silicon nitride is between 10:90 and 99:1. Herein, the barium silicate can secure the silicon nitride to avoid the silicon nitride from peeling off. Referring to FIGS. 4H and 4I both, FIG. 4H represents that a release coating layer 120′ further includes 40% by weight of silicon nitride, FIG. 41 represents that a release coating layer 120″ further includes 70% by weight of silicon nitride. Experiments show that the silicon nitride and barium carbonate have good wetting performance with different mixing ratio, thereby effectively preventing the problem of sticking to crucible. Furthermore, experiments also show that a continuous barium silicate can be observed in the release coating layer 120′ and 120″. In addition, the release coating layers 120′ and 120″ containing silicon nitride has an equivalent lifetime mapping as conventional silicon nitride coating layer.

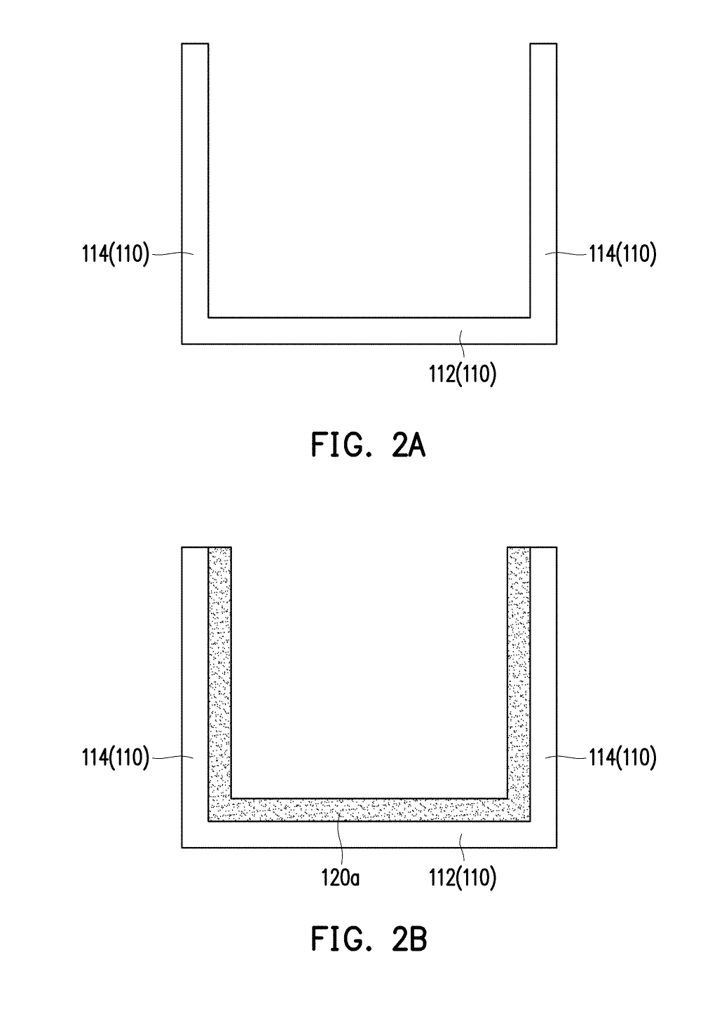

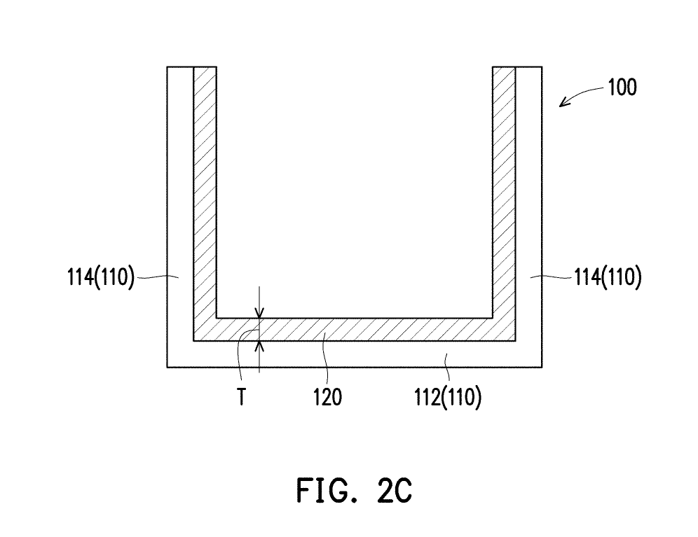

FIGS. 2A to 2C are schematic views illustrating a manufacturing method of a crucible structure according to an embodiment of the invention. Regarding the manufacturing process, please refer to FIG. 2A first, a crucible body 110 is provided, and the material of the crucible body 110 includes silica, where the crucible body 110 has a bottom surface 112 and a side surface 114 connected with the bottom surface 112. Herein, the crucible body 110 is formed by hot-pressing quartz sand.

Thereafter, referring to FIG. 2B, the raw material of releasing coating layer 120a containing a barium compound material is coated on the crucible body 110. The step of coating the raw material of release coating layer 120a on the crucible body 110 includes spraying the barium compound material having barium carbonate, barium oxide or barium hydroxide on the crucible body 110, wherein the amount of barium compound material sprayed is between 0.3×10⁻² g/cm² and 5×10⁻² g/cm². Since the barium carbonate cannot be dissolved in water, the adhesion of coating can be enhanced by aqueous binder solution, wherein the aqueous binder solution is, for example, polyvinyl alcohol aqueous solution. Alternatively, the binder may be tetraethyl orthosilicate, colloidal silica or polyvinylpyrrolidone, the invention provides no limitation thereto. Thereafter, the barium compound material may be heated at an appropriate temperature to be dried. Herein, the barium carbonate may be acquired directly or can be formed via reaction of barium hydroxide with carbon dioxide in the air, which should not be construed as a limitation to the invention.

Finally, referring to FIG. 2C, the crucible body 110 and the raw material of release coating layer 120a are heated such that the raw material of release coating layer 120a is reacted with the crucible body 110 to form the release coating layer 120 that directly covers the crucible body 110. The material of the release coating layer 120 includes barium silicate, wherein the barium silicate is a continuous film, and the thickness T of the release coating layer 120 is between 35 μm and 350 μm. Herein, the temperature for heating the crucible body 110 and the raw material of release coating layer 120a is between 1200° C. and 1400° C. , and the time for heating the crucible body 110 and raw material of release coating layer 120a is between 5 hours and 15 hours. At this point, the fabrication of crucible structure 100 has been completed. It should be pointed out that, in other embodiment, apart from using a heating furnace and/or ingot growth furnace for heating, other heating methods such as use of infrared ray can be used. In addition, the heating process can be performed together with the use of crucible fixing apparatus to prevent the crucible from being damaged.

In brief, the crucible structure 100 in the embodiment uses the raw material (i.e. can be solely the barium compound material, or a mixture of the barium compound material and silicon nitride) of release coating layer 120a with the barium compound material having barium carbonate, barium oxide or barium hydroxide in replace of conventional silicon nitride layer. By being heated with the crucible body 110, the raw material of release coating layer 120a is formed into the release coating layer 120 that directly covers the crucible body 110 with the material including barium silicate or a mixture of barium silicate and silicon nitride. The barium silicate is a continuous film, and the thickness T of the release coating layer 120 is between 35 μm and 350 μm. As compared with the spraying cost of conventional crucible, since the crucible structure 100 in the embodiment uses the release coating layer 120, not only that the manufacturing cost can be reduced effectively, the probability that impurities falling into the subsequently formed silicon crystal structure can be effectively decreased or avoided.

It should be indicated that the following embodiments use the reference numerals and a part of the descriptions mentioned in the previous embodiments, wherein the same reference numbers are used to denote identical or similar elements. Meanwhile, the same technical content is omitted. Please refer to the previous embodiments for the omitted descriptions; no repetitions are incorporated into the following embodiments.

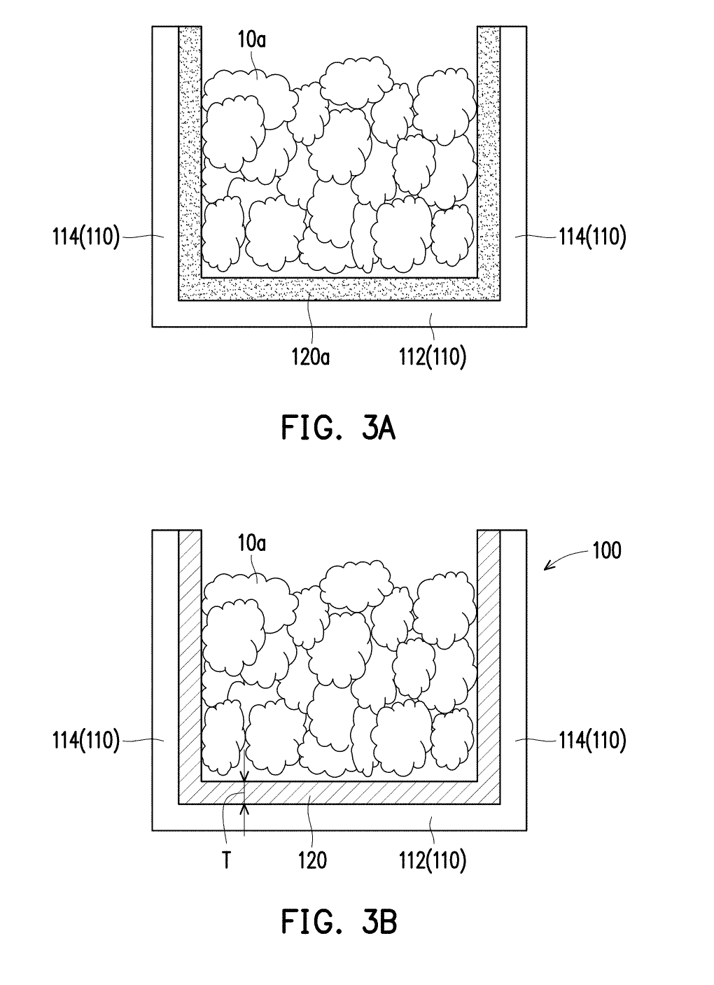

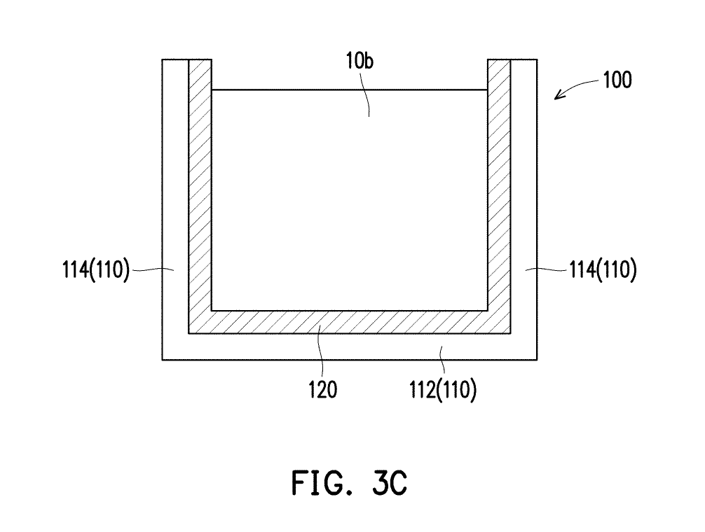

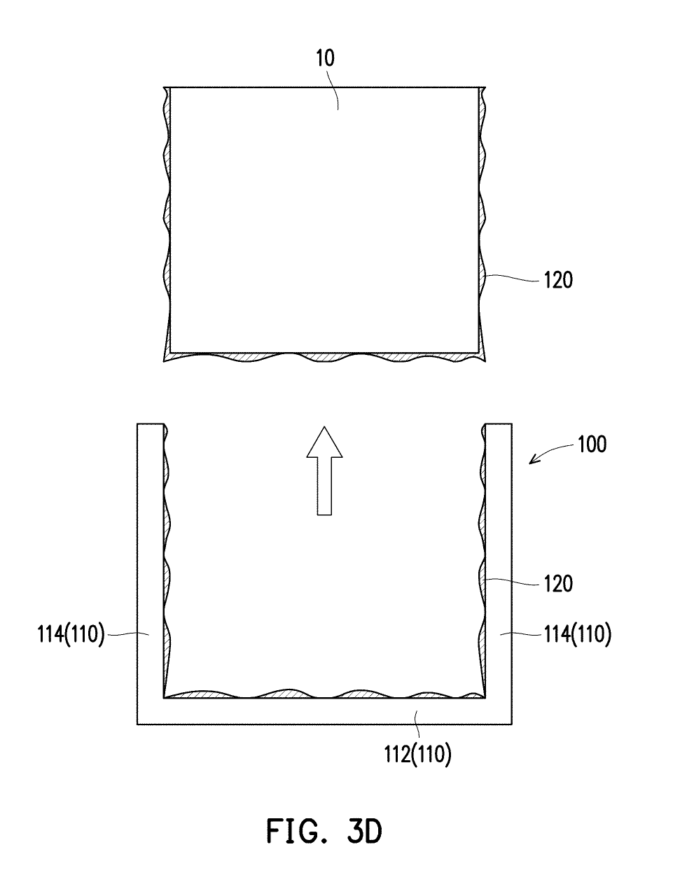

FIGS. 3A to 3D are schematic views illustrating a manufacturing method of a silicon crystal structure according to an embodiment of the invention. Referring to FIG. 3A, in accordance with the manufacturing method of the silicon crystal structure of the embodiment, first of all, like the steps illustrated in FIGS. 2A and 2B, the crucible body 110 is provided, and the raw material of release coating layer 120a containing the barium compound material is coated on the crucible body 110. Thereafter, a silicon material 10a is filled in the crucible body 110, wherein the raw material of release coating layer 120a is disposed between the crucible body 110 and silicon material 10a. Herein, the silicon material 10a is specifically a material for crystal growth.

Referring to FIG. 3B, the crucible body 110, the raw material of release coating layer 120a and the silicon material 10a are heated to a first temperature so that the raw material of release coating layer 120a and the crucible body 110 are reacted to form the release coating layer 120 that directly covers the crucible body 110. The first temperature is realized as a melting temperature lower than that of the silicon material 10a, and the first temperature is, for example, between 1200° C. and 1400° C. ; the crucible body 110, the raw material of release coating layer 120a and the silicon material 10a are heated to the first temperature for a time period between 10 hours and 20 hours, for example. The heating step at the first stage is to make the raw material of release coating layer 120a to be reacted with the crucible body 110 so as to form the release coating layer 120. Therefore, the temperature for heating cannot be higher than the melting temperature of the silicon material 10a, and sufficient reaction temperature and reaction time are required. Herein, the material for forming the release coating layer 120 includes barium silicate (that is, that material may be barium silicate, or a mixture of barium silicate and silicon nitride), wherein the barium silicate is a continuous film and the thickness T of the release coating layer 120 is between 35 μm and 350 μm.

Next, referring to FIG. 3C, the crucible body 110, the release coating layer 120 and the silicon material 10a are heated from the first temperature to a second temperature so that the silicon material 10a is formed into a molten silicon material 10b. Herein, the second temperature is greater than the melting temperature of the silicon material 10a, and the second temperature is, for example, between 1412° C. and 1600° C. The time for heating the crucible body 110, the release coating layer 120 and the silicon material 10a from the first temperature to the second temperature is, for example, between 10 hours and 20 hours. The heating step at the second stage is to carry out heating continuously from the first temperature to the second temperature for the purpose of making the silicon material 10a to form into the molten silicon material 10b to conduct crystal growth operation. Therefore, the second temperature has to be greater than the melting temperature of the silicon material 10a.

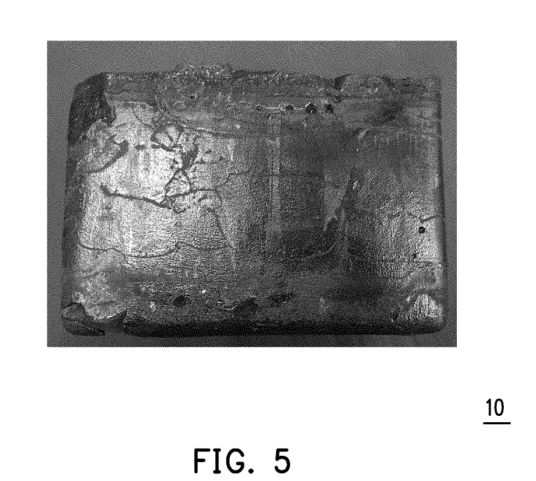

Subsequently, referring to FIG. 3D, the crucible body 110 is cooled so that the molten silicon material 10b is formed into a silicon crystal structure 10 which directly contacts the release coating layer 120. Lastly, the silicon crystal structure 10 is moved out from the crucible structure 100 and the crucible structure 100 is removed. Herein, the silicon crystal structure 10 is, for example, a multi-ingot, a quasi-single crystal ingot or a casted single ingot, which should not be construed as a limitation to the invention, and the surface thereof has metallic gloss. Referring to FIG. 5, the central-line average roughness (Ra) of the silicon crystal structure 10 is, for example, between 2 μm and 15 μm. At this point, the fabrication of the silicon crystal structure 10 is completed.

Briefly, in the manufacturing method of the silicon crystal structure 10 described in the embodiment, the formation of the release coating layer 120 and the formation of silicon crystal structure 10 are combined into a single batch reaction. That is, the raw material of release coating layer 120a and the crucible body 110 are reacted first to form the release coating layer 120 that directly covers the crucible body 110, and then the silicon crystal structure 10 is formed. The above manufacturing method makes it possible to avoid the problem the high temperature causes the crucible body 110 to be softened while ensuring completeness of the reaction of the release coating layer 120. Accordingly, the cost for performing spraying powder on the crucible body 110 can be reduced and the probability that the impurity permeating through the silicon crystal structure 10 can be effectively decreased or avoided. It should be pointed out that, in the manufacturing method of the silicon crystal structure 10 performed in other embodiments, as long as the crucible structure in the above embodiment is not substantially damaged after completion, the crucible structure in the above embodiments can be used directly to conduct the subsequent crystal growth process without having to be combined for the single batch reaction. The crystal growth process is a conventional technology, and therefore no further descriptions are incorporated herein.

In summary of the above, the crucible structure of the invention uses the release coating layer that contains barium silicate or a mixture of barium silicate and silicon nitride as the material in replace of conventional purity silicon nitride layer, wherein the barium silicate is a continuous film for contacting the silicon crystal structure, and the thickness of the release coating layer is between 35 μm and 350 μm. As compared with the spraying cost for conventional crucible, the release coating layer used for the crucible structure of the invention not only can effectively lower the manufacturing cost, but also effectively reduce or avoid the probability that impurity falls into the silicon crystal structure formed in the subsequent process.

In addition, in the manufacturing method of the silicon crystal structure of the invention, the formation of the release coating layer and the formation of the silicon crystal structure are combined as a single batch reaction. That is, the raw material of release coating layer is reacted with the crucible body first to form the release coating layer that directly covers the crucible body, and the silicon crystal structure is formed afterwards. The above method can avoid the problem that high temperature causes the crucible body to be softened while ensuring completeness of reaction of the release coating layer. Accordingly, the spraying cost required for the crucible body can be decreased, and the probability that impurity falls into the silicon crystal structure can be effectively reduced or avoided.

Although the invention has been disclosed by the above embodiments, the embodiments are not intended to limit the invention. It will be apparent to those skilled in the art that various modifications and variations can be made to the structure of the invention without departing from the scope or spirit of the invention. Therefore, the protecting range of the invention falls in the appended claims.

What is claimed is:

1. A crucible structure, adapted for manufacturing a silicon crystal structure, the crucible structure comprising:
a crucible body, a material of the crucible body comprises silica; and
a release coating layer, directly covering the crucible body, a material of the release coating layer comprising barium silicate, wherein the barium silicate is a continuous film used for contacting the silicon crystal structure, and a thickness of the release coating layer is between 35 μm and 350 μm.

2. The crucible structure according to claim 1, wherein the crucible body is formed by hot-pressing quartz sand.

3. The crucible structure according to claim 1, wherein a central-line average roughness of the crucible body is between 5 μm and 35 μm.

4. The crucible structure according to claim 1, further comprising:
a middle layer, disposed between the crucible body and the release coating layer, wherein the middle layer comprises 80% to 100% by weight of silica.

5. The crucible structure according to claim 1, wherein a material of the release coating layer further comprises silicon nitride, and a ratio of the barium silicate to the silicon nitride is between 10:90 and 99:1.

6. The crucible structure according to claim 1, wherein the release coating layer is a barium silicate coating layer.

7. A manufacturing method of a crucible structure, the crucible structure is adaptable for manufacturing a silicon crystal structure, comprising:
providing a crucible body, wherein a material of the crucible body comprise silica;
coating a raw material of release coating layer having a barium compound on the crucible body; and
heating the crucible body and the raw material of release coating layer to form a release coating layer which directly covers the crucible body, a material of the release coating layer comprises barium silicate, wherein the barium silicate is a continuous film for contacting the silicon crystal structure, and a thickness of the release coating layer is between 35 μm and 350 μm.

8. The manufacturing method of the crucible structure according to claim 7, wherein the step of coating the raw material of release coating layer on the crucible body comprises:
spraying the barium compound material comprising barium carbonate or barium hydroxide on the crucible body.

9. The manufacturing method of the crucible structure according to claim 8, wherein the barium compound material is sprayed in an amount of 0.3×10⁻² g/cm² to 5×10⁻² g/cm².

10. The manufacturing method of the crucible structure according to claim 7, wherein the crucible body is formed by hot-pressing quartz sand.

11. The manufacturing method of the crucible structure according to claim 7, wherein a material of the raw material of release coating layer further comprises silicon nitride, and a ratio of the barium compound material to the silicon nitride is between 10:90 and 99:1.

12. The manufacturing method of the crucible structure according to claim 7, wherein the release coating layer is a barium silicate coating layer.

13. A manufacturing method of a silicon crystal structure, comprising:
providing a crucible body, a material of the crucible body comprises silica;
coating a raw material of release coating layer containing a barium compound material on the crucible body;
filling a silicon material on the crucible body, the raw material of release coating layer is disposed between the crucible body and the silicon material;
heating the crucible body, the raw material of release coating layer and the silicon material to a first temperature to form a release coating layer which directly covers the crucible body, a material of the release coating layer comprises barium silicate, wherein the barium silicate is a continuous film for contacting the silicon crystal structure, and a thickness of the release coating layer is between 35 μm and 350 μm;
heating the crucible body, the release coating layer and the silicon material from the first temperature to a second temperature so that the silicon material is formed into a molten silicon material; and
cooling the crucible body so that the molten silicon material is formed to directly contact the silicon crystal structure of the release coating layer.

14. The manufacturing method of the silicon crystal structure according to claim 13, wherein the first temperature is lower than a melting temperature of the silicon material, and the first temperature is between 1200° C. and 1400° C.

15. The manufacturing method of the silicon crystal structure according to claim 13, wherein the second temperature is higher than a melting temperature of the silicon material, and the second temperature is between 1412° C. and 1600° C.

16. The manufacturing method of the silicon crystal structure according to claim 13, wherein the step of coating the raw material of release coating layer on the crucible body comprises spraying the barium compound material having barium carbonate or barium hydroxide on the crucible body.
